(19) United States
(12) Patent Application Publication
(10) Pub. No.: US 2016/0376710 A1
(43) Pub. Date: Dec. 29, 2016

(54) METHOD AND APPARATUS TO ABATE PYROPHORIC BYPRODUCTS FROM ION IMPLANT PROCESS

(71) Applicant: Applied Materials, Inc., Santa Clara, CA (US)

(72) Inventors: Dustin W. HO, Shanghai (CN); Michael S. COX, Gilroy, CA (US); Zheng YUAN, Santa Clara, CA (US)

(21) Appl. No.: 15/187,838

(22) Filed: Jun. 21, 2016

(30) Foreign Application Priority Data
Jun. 23, 2015 (CN) 201510350247.0

(51) Int. Cl. C23C 22/82; C23C 16/02

(52) U.S. Cl. CPC C23C 22/82; C23C 16/0245

(57) ABSTRACT

Embodiments disclosed herein generally relate to plasma abatement processes and apparatuses. A plasma abatement process takes effluent from a foreline of a processing chamber, such as an implant chamber, and reacts the effluent with a reagent. The effluent contains a pyrophoric byproduct. A plasma generator placed within the foreline path may ionize the effluent and the reagent to facilitate a reaction between the effluent and the reagent. The ionized species react to form compounds which remain in a gaseous phase at conditions within the exhaust stream path. In another embodiment, the ionized species may react to form compounds which condense out of the gaseous phase. The condensed particulate matter is then removed from the effluent by a trap. The apparatuses may include an implant chamber, a plasma generator, one or more pumps, and a scrubber.

### CROSS-REFERENCE TO RELATED APPLICATIONS

This application claims benefit of Chinese Patent Application No. 201510350247.0, filed Jun. 23, 2015, which is herein incorporated by reference.

### BACKGROUND

1. Field

Embodiments of the present disclosure generally relate to abatement for semiconductor processing equipment. More particularly, embodiments of the present disclosure relate to techniques for abating pyrophoric compounds present in the effluent of semiconductor processing equipment.

2. Description of the Related Art

Effluent produced during semiconductor manufacturing processes includes many compounds which must be abated or treated before disposal, due to regulatory requirements and environmental and safety concerns. Among these compounds are pyrophoric materials present in the effluent from implant processes. Such gases and particulate matter are harmful to both human health and the environment, along with being harmful to semiconductor processing equipment, such as processing pumps.

Accordingly, what is needed in the art is improved abatement methods and apparatuses.

### SUMMARY

In one embodiment, a method comprises flowing an effluent from a processing chamber into a plasma generator when the effluent comprises a pyrophoric material. The method further comprises flowing a reagent into the plasma generator and ionizing one or more of the pyrophoric material and reagent. After the ionizing, the pyrophoric material is reacted with the reagent to generate a gas phase effluent material. The gas phase effluent material is abated.

In another embodiment, a method of abating effluent from a processing chamber comprises flowing an effluent from a processing chamber into a plasma generator when the effluent comprises a pyrophoric material. The method further comprises flowing a reagent into the plasma generator and ionizing one or more of the pyrophoric material and the reagent. After the ionizing, the pyrophoric material is reacted with the reagent to generate condensed particulate matter. The condensed particulate matter is then trapped.

In another embodiment, an apparatus for abating effluent from a processing chamber comprises an ion implant chamber. A foreline is coupled to the ion implant chamber for exhausting effluent from the ion implant chamber. The apparatus also includes a plasma generator for generating ionized gases within the foreline. A vacuum source is coupled to the foreline downstream of the plasma generator. A scrubber is fluidly coupled to the vacuum source.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 depicts a schematic diagram of a substrate processing system, according to one embodiment of the disclosure.

FIG. 2A is a cross sectional perspective view of a plasma generator, according to one embodiment of the disclosure.

FIG. 2B is a cross sectional view of the plasma generator of FIG. 2A, according to one embodiment of the disclosure.

FIG. 2C is an enlarged view of a metal shield of the plasma generator of FIG. 2A, according to one embodiment of the disclosure.

FIG. 3 is a flow diagram illustrating one embodiment of a method of abating effluent exiting a processing chamber.

FIG. 4 depicts a schematic diagram of a substrate processing system, according to another embodiment of the disclosure.

FIG. 5 is a flow diagram illustrating another embodiment of a method of abating effluent exiting a processing chamber.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Embodiments disclosed herein generally relate to plasma abatement processes and apparatuses. A plasma abatement process takes effluent from a foreline of a processing chamber, such as an implant chamber, and reacts the effluent with a reagent when the effluent contains a pyrophoric byproduct. A plasma generator placed within the foreline path may ionize the effluent and the reagent to facilitate a reaction between the effluent and the reagent. The ionized species react to form compounds which remain in a gaseous phase at conditions within the exhaust stream path. In another embodiment, the ionized species may react to form compounds which condense out of the gaseous phase. The condensed particulate matter is then removed from the effluent by a trap. The apparatuses may include an implant chamber, a plasma generator, one or more pumps, and a scrubber.

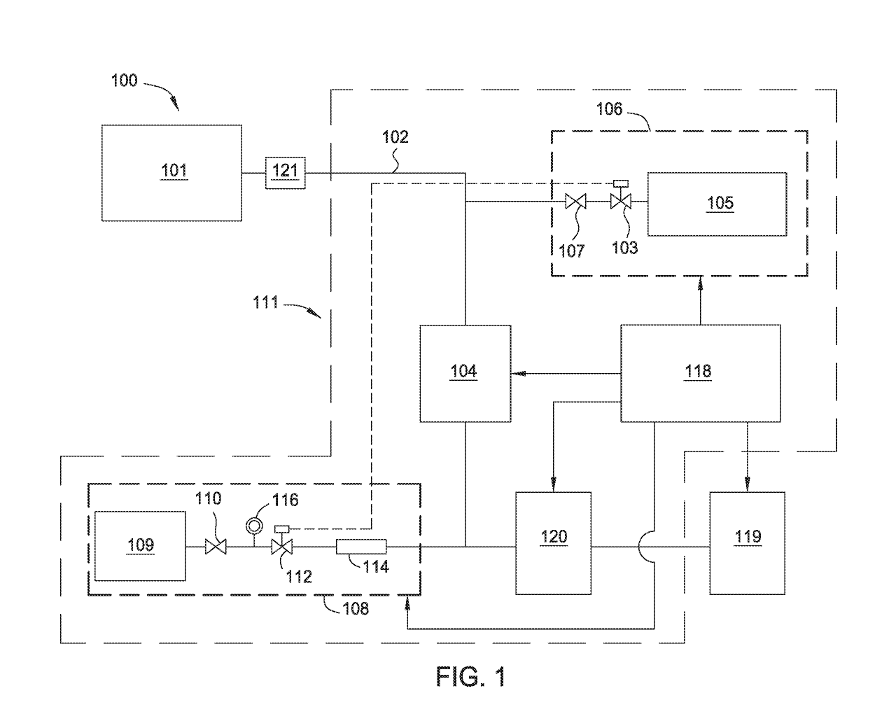

FIG. 1 depicts a schematic diagram of a processing system 100 in accordance with the embodiments disclosed herein. The processing system 100 includes a processing chamber 101 coupled to a scrubber 119 through an abatement system 111. As shown in FIG. 1, the foreline 102 couples a processing chamber 101 with the abatement system 111. A pump 121, such as a turbo molecular pump (TMP), may be fluidly coupled to the processing chamber 101 to facilitate evacuation of process gases from the processing chamber 101 into the foreline 102. The processing chamber 101 may be, for example, an ion implant chamber such as a ribbon implanter, a plasma immersion ion implanter, and the like. Exemplary ion implant chambers are available from Applied Materials, Inc., of Santa Clara, Calif.

The foreline 102 serves as a conduit that routes effluent leaving the processing chamber 101 to the abatement system 111. One example of an abatement system 111 that may be utilized is a ZFP2™ abatement system available from Applied Materials, Inc., located in Santa Clara, Calif., among other suitable systems. As shown, the abatement system 111 includes a plasma generator 104, a reagent delivery system 106, a foreline gas injection kit 108, a controller 118, and a vacuum source 120. Foreline 102 provides effluent leaving the processing chamber 101 to the plasma generator 104.

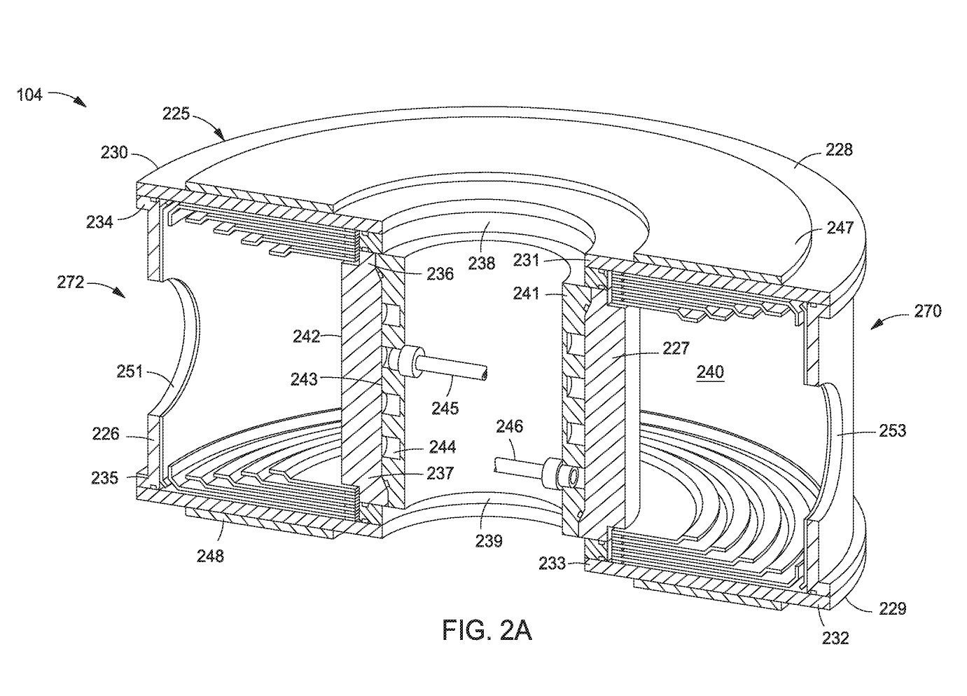

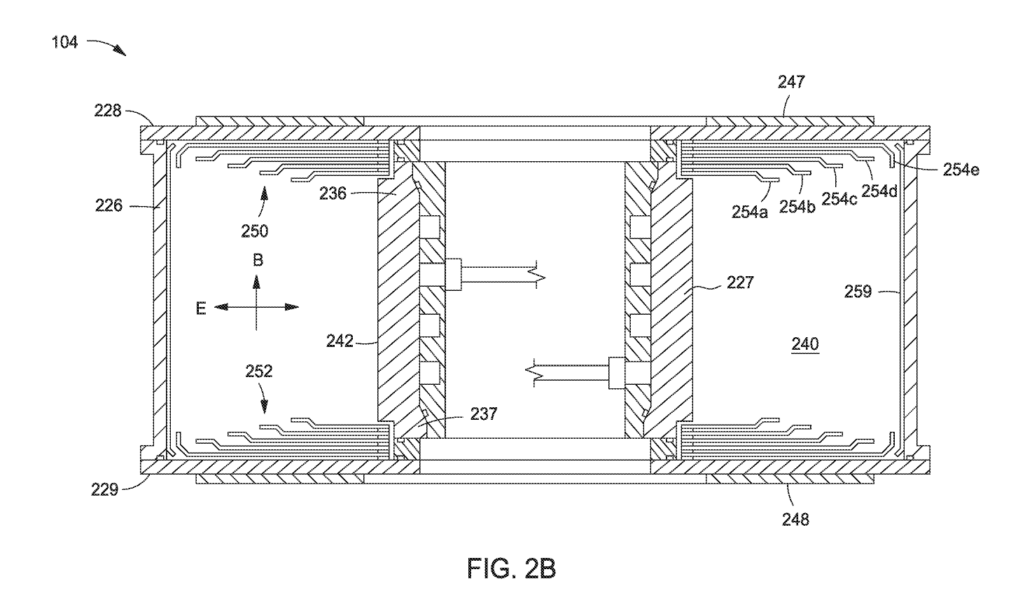

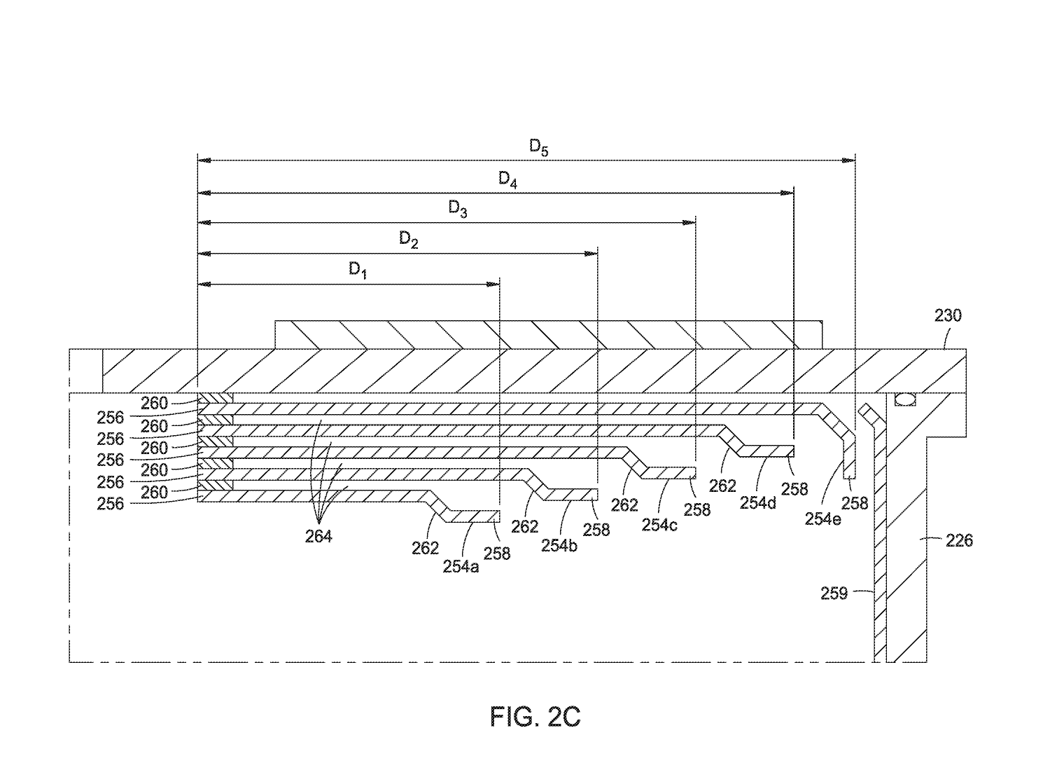

The plasma generator 104 may be any plasma generator coupled to the foreline 102 suitable for generating a plasma therein. For example, the plasma generator 104 may be a remote plasma generator, an in-line plasma generator, or other suitable plasma generator for generating a plasma within the foreline 102 or proximate the foreline 102 for introducing reactive species into the foreline 102. The plasma generator 104 may be, for example, an inductively coupled plasma generator, a capacitively coupled plasma generator, a direct current plasma generator, or a microwave plasma generator. The plasma generator 104 may further be a magnetically enhanced plasma generator. In one embodiment, the plasma generator 104 is a plasma generator as described with reference to FIGS. 2A-2C.

The foreline gas injection kit 108 may be coupled to the foreline 102 upstream or downstream of the plasma generator 104 (downstream depicted in FIG. 1) to facilitate movement of gases through the foreline 102. The foreline gas injection kit 108 may controllably provide a foreline gas, such as nitrogen (N₂), argon (Ar), or clean dry air, into the foreline 102 to control the pressure within the foreline 102. The foreline gas injection kit 108 may include a foreline gas source 109 followed by a pressure regulator 110, further followed by a control valve 112, and even further followed by a flow control device 114. The pressure regulator 110 sets the gas delivery pressure set point. The control valve 112 turns on and off the gas flow. The control valve 112 may be any suitable control valve, such as a solenoid valve, pneumatic valve or the like. The flow control device 114 provides a flow rate of gas specified by the set point of pressure regulator 110. The flow control device 114 may be any suitable active or passive flow control device, such as a fixed orifice, mass flow controller, needle valve, or the like.

In some embodiments the foreline gas injection kit 108 may further include a pressure gauge 116. The pressure gauge 116 may be disposed between the pressure regulator 110 and the flow control device 114. The pressure gauge 116 may be used to measure pressure in the foreline gas injection kit 108 upstream of the flow control device 114. The measured pressure at the pressure gauge 116 may be utilized by a control device, such as a controller 118, to set the pressure upstream of the flow control device 114 by controlling the pressure regulator 110.

The reagent delivery system 106 may also be coupled with the foreline 102. The reagent delivery system 106 delivers one or more reagents to the foreline 102 upstream of the plasma generator 104. In an alternative embodiment, the reagent delivery system 106 may be coupled directly to the plasma generator 104 for delivering reagents directly into the plasma generator 104. The reagent delivery system 106 may include one or more reagent sources 105 (one is shown) coupled to the foreline 102 (or the plasma generator 104) via one or more valves. For example, in some embodiments, a valve scheme may include a two-way control valve 103, which functions as an on/off switch for controlling the flow the one or more reagents from the reagent source 105 into the foreline 102, and a flow control device 107, which controls the flow rates of the one or more reagents into the foreline 102. The flow control device 107 may be disposed between the foreline 102 and the control valve 103. The control valve 103 may be any suitable control valve, such as a solenoid valve, pneumatic valve, or the like. The flow control device 107 may be any suitable active or passive flow control device, such as a fixed orifice, mass flow controller, needle valve, or the like.

The foreline gas injection kit 108 may be controlled by the controller 118 to only deliver gas when the reagent from the reagent delivery system 106 is flowing, such that usage of gas is minimized. For example, as illustrated by the dotted line between control valve 103 of the reagent delivery system 106 and the control valve 112 of the foreline gas injection kit 108, the control valve 112 may turn on (or off) in response to the control valve 103 being turned on (or off). In such an embodiment, flow of gases from the foreline gas injection kit 108 and the reagent delivery system 106 may be linked. Additionally, the controller 118 may be coupled to various components of the processing system 100 to control the operation thereof. For example, the controller may monitor and/or control the foreline gas injection kit 108, the reagent delivery system 106, the scrubber 119, and/or the plasma generator 104 in accordance with the teachings disclosed herein.

The foreline 102 may be coupled to a vacuum source 120 or other suitable pumping apparatus. The vacuum source 120 facilitates pumping of the effluent from the processing chamber 101 to appropriate downstream effluent handling equipment, such as to the scrubber 119, an incinerator, (not shown), or the like. In one example the scrubber 119 may be an alkaline dry scrubber or a water scrubber. In some embodiments, the vacuum source 120 may be a backing pump or a roughing pump, such as a dry mechanical pump or the like. The vacuum source 120 may have a variable pumping capacity which can be set at a desired level, for example, to facilitate control of pressure in the foreline 102.

During operation of the processing system 100, effluent that contains undesirable material exits the processing chamber 101 into the foreline 102. The effluent exhausted from the processing chamber 101 into the foreline 102 may contain material which is undesirable for release into the atmosphere or may damage downstream equipment, such as vacuum pumps. For example, the effluent may contain pyrophoric materials that are byproducts from an ion implant process. Examples of materials present in the effluent that may be abated using the methods disclosed herein include one or more of P, B, As, PH₃, BH₃, AsH₃, and derivatives thereof.

In conventional abatement systems, as the effluent gas travels through an abatement system, the pressure of the effluent gas approaches or reaches atmospheric pressure. As the effluent gas reaches atmospheric pressure, some pyrophoric compounds condensate on internal components of the abatement system. For example, phosphorus condensates from the effluent onto internal components of the abatement system at a temperature of about 280 degrees Celsius at atmospheric pressure. As condensate builds up, the condensate should be removed to facilitate efficient operation of the abatement system. Removal of the condensate may involve exposing pyrophoric condensate to air, which could result in a hazardous situation.

The processing system 100 obviates the need for removing condensate from the abatement system 111 by reducing or preventing the formation of pyrophoric condensate. In particular, the abatement system 111 reacts pyrophoric byproducts with a reagent to create gas phase effluent materials which remain in the gas phase as the effluent materials travel through the abatement system 111. In one example, the gas phase effluent materials derived from the pyrophoric byproducts remain in a gas phase at pressure of about 760 torr and temperature of about 200 degrees Celsius. Thus, the gas phase effluent materials can be exhausted to the scrubber 219 without condensing on internal surfaces of the abatement system 111. Reaction of the pyrophoric byproducts to the gas phase effluent materials is facilitated by exposure of the pyrophoric byproducts to a reagent gas, and ionizing one or more of the pyrophoric byproduct and the reagent gas.

In the processing system 100, effluent containing a pyrophoric byproduct from the processing chamber 101 and a reagent from the reagent delivery system 106 are delivered to the plasma generator 104. A plasma is generated from the reagent and/or the effluent within the plasma generator 104, thereby energizing the reagent and/or the effluent. In some embodiments, at least some of the reagent and the effluent are at least partially disassociated. The identity of the reagent, the flow rate of the reagent, the foreline gas injection parameters, and the plasma generation conditions may be determined based on the composition of the material entrained in the effluent and may be controlled by the controller 118. In an embodiment where the plasma generator 104 is an inductively coupled plasma generator, dissociation may require several kW of power. Dissociation of the pyrophoric byproduct of the effluent and the reagent facilitates the formation of products which remain in the gaseous phase under conditions found in the abatement system 111. The gas phase effluent materials may then be exhausted to the scrubber 119 without condensing within the abatement system 111.

FIG. 2A is a cross sectional perspective view of the plasma generator 104 according to one embodiment of the disclosure. The plasma generator 104 includes a body 225 having an outer wall 226, an inner wall 227, a first plate 228, and a second plate 229. The first plate 228 and the second plate 229 are ring-shaped, while the outer and inner walls 226, 227 are cylindrical. The inner wall 227 may be a hollow electrode which may be coupled to an RF source (not shown). The outer wall 226 may be grounded. The first plate 228 and the second plate 229 may be concentrically aligned. The first plate 228 includes an outer edge 230 and an inner edge 231. The second plate 229 includes an outer edge 232 and an inner edge 233. The outer wall 226 includes a first end 234 and a second end 235. The inner wall 227 includes a first end 236 and a second end 237.

A first insulating ring 238 is disposed adjacent to the first end 236 of the inner wall 227 and a second insulating ring 239 is disposed adjacent to the second end 237 of the inner wall 227. The insulating rings 238, 239 may be made of an insulating ceramic material. The outer edge 230 of the first plate 228 may be disposed adjacent to the first end 234 of the outer wall 226. The outer edge 232 of the second plate 229 may be disposed adjacent to the second end 235 of the outer wall 226. In one embodiment, the ends 234, 235 of the outer wall 226 are in contact with the outer edges 230, 232, respectively. The inner edge 231 of the first plate 228 may be adjacent to the first insulating ring 238, and the inner edge 233 of the second plate 229 may be adjacent to the second insulating ring 239. A plasma region 240 is defined between the outer wall 226 and the inner wall 227, and between the first plate 228 and the second plate 229. A capacitively coupled plasma may be formed in the plasma region 240.

In order to keep the inner wall 227 cool during operation, a cooling jacket 241 may be coupled to the inner wall 227. The inner wall 227 may have a first surface 242 facing the outer wall 226 and a second surface 243 opposite the first surface. The cooling jacket 241 may have a cooling channel 244 formed therein, and the cooling channel 244 is coupled to a coolant inlet 245 and a coolant outlet 246 for flowing a coolant, such as water, into and out of the cooling jacket 241.

A first plurality of magnets 247 is disposed on the first plate 228. In one embodiment, the first plurality of magnets 247 may be a magnetron having an array of magnets and may have an annular shape. A second plurality of magnets 248 is disposed on the second plate 229. The second plurality of magnets 248 may be a magnetron having an array of magnets. The second plurality of magnets 248 may have the same shape as the first plurality of magnets 247. The magnets 247, 248 may have opposite polarities facing the plasma region 240. The magnets 247, 248 may be rare-earth magnets, such as neodymium ceramic magnets. One or more gas injection ports 251, 253 may be formed within the plasma generator 104 for introducing a gas to the plasma generator 104.

FIG. 2B is a cross sectional view of the plasma generator 104 according to one embodiment of the disclosure. During operation, the inner wall 227 is powered by a radio frequency (RF) power source and the outer wall 226 is grounded, forming an oscillating or constant electric field “E” in the plasma region 240, depending on the type of applied power, RF or direct current (DC), or some frequency in between. Bi-polar DC and bi-polar pulsing DC power may also be used with inner and outer walls forming the two opposing electrical poles. The magnets 247, 248 create a largely uniform magnetic field “B” that is substantially perpendicular to the electric field “E.” In this configuration, a resulting force causes the current that would normally follow the electric field “E” to curve towards the second end 272 (out of the paper), and this force raises the plasma density significantly by limiting plasma electron losses to the grounded wall. In the case of applied RF power, this would result in an annular oscillating current directed largely away from the grounded wall. In the case of applied DC power, this would result in a constant annular current directed largely away from the grounded wall.

This effect of current divergence from the applied electric field is known as the “Hall effect.” The plasma formed in the plasma region 240 dissociates at least a portion of the by-products in the effluent flowing in from the gas injection port 253 at the first end 270 to the gas injection port 251 at the second end 272. A reagent may be also injected into the plasma region 240 to react with the dissociated effluent to form gas phase effluent materials. In one embodiment, the gas phase effluent materials remain in the gas phase at temperatures and pressures common within an effluent system.

A first metal shield 250 may be disposed inside the plasma region 240 adjacent to the first plate 228. A second metal shield 252 may be disposed inside the plasma region 240 adjacent to the second plate 229. A third metal shield 259 may be disposed in the plasma region adjacent to the outer wall 226. Shields 250, 252, 259 may be removable, replaceable and/or reusable to facilitate maintenance of the plasma generator 104. The first metal shield 250 and the second metal shield 252 may have a similar configuration. In one embodiment, both the first metal shield 250 and the second metal shield 252 have an annular shape. The first metal shield 250 and the second metal shield 252 each include a stack of metal plates 254a-254e that are isolated from one another.

FIG. 2C is an enlarged view of the first metal shield 250 according to one embodiment of the disclosure. Each plate 254a-254e is annular and includes an inner edge 256 and an outer edge 258. The metal plates 254a-254e may be coated to change shield surface emissivity via anodization to improve chemical resistance, radiant heat transfer, and stress reduction. In one embodiment, the metal plates 254a-254e are coated with black color aluminum oxide. An inner portion 264 of the metal plate 254a may be made of a ceramic material for arcing prevention and dimensional stability. The inner edge 256 of the metal plates 254a-254e are separated from one another by an insulating washer 260, so the metal plates 254a-254e are electrically isolated from one another. The insulating washer 260 also separates the metal plate 254e from the first plate 228. The stack of metal plates 254a-254e may be secured in position by one or more ceramic rods or spacers (not shown).

In one embodiment, the distance D1 between the inner edge 256 and the outer edge 258 of the plate 254a is smaller than the distance D2 between the inner edge 256 and the outer edge 258 of the plate 254b. The distance D2 is smaller than the distance D3 between the inner edge 256 and the outer edge 258 of the plate 254c. The distance D3 is smaller than the distance D4 between the inner edge 256 and the outer edge 258 of the plate 254d. The distance D4 is smaller than the distance D5 between the inner edge 256 and the outer edge 258 of the plate 254e. In other words, the distance between the inner edge 256 and the outer edge 258 is related to the location of the plate, e.g., the further the plate is disposed from the plasma region, the greater distance between the inner edge 256 and the outer edge 258.

The spaces between the metal plates 254a-254e may be dark spaces, which may be bridged with materials deposited on the plates, causing the plates to be shorted out to each other. To prevent this from happening, in one embodiment, each metal plate 254a-254e includes a step 262 so the outer edge 258 of each metal plate 254a-254e is distanced from an adjacent plate. The step 262 causes the outer edge 258 to be non-linear with the inner edge 256. Each step 262 shields the inner portion 264 formed between adjacent metal plates, so as to reduce material deposition on the inner portion 264.

The outer wall 226, the inner wall 227, and the shields 250, 252, 259 may be all made of metal. In one embodiment, the metal may be stainless steel, such as 316 stainless steel. The insulating rings 238, 239 may be made of quartz. In another embodiment, the metal may be aluminum and the insulating rings 238, 239 may be made of alumina. The inner wall 227 may be made of anodized aluminum or spray-coated aluminum.

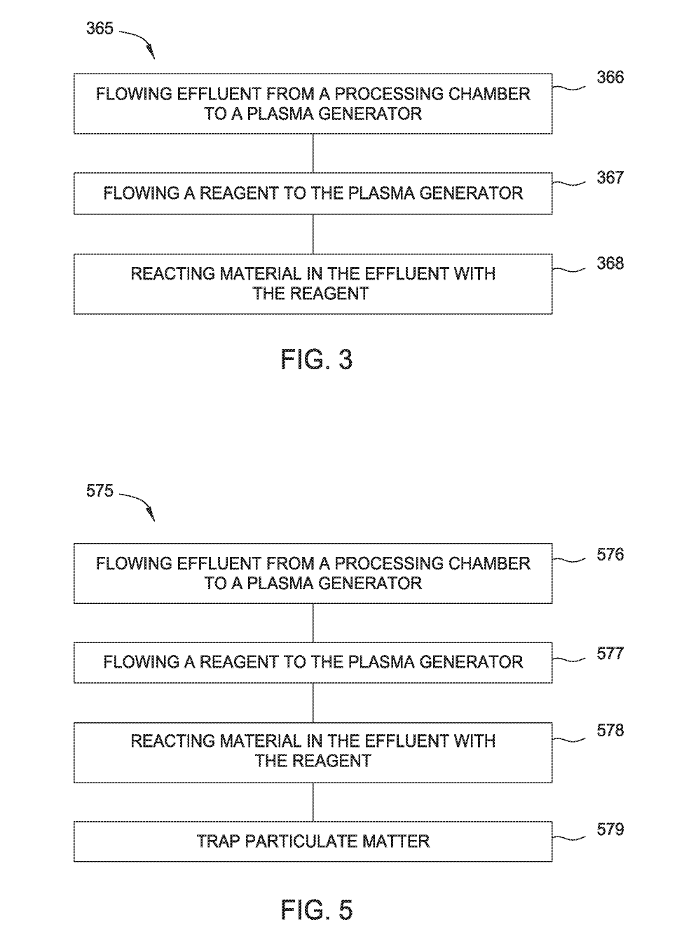

FIG. 3 is a flow diagram illustrating one embodiment of a method 365 of abating effluent exiting a processing chamber. The method 365 begins at operation 366. In operation 366, an effluent containing a pyrophoric byproduct is exhausted from a processing chamber, such as processing chamber 101, into a plasma generator, such as plasma generator 104. A pump, such as the pump 121, facilitates removal of the effluent from the processing chamber. During operation 367, a reagent is introduced to the plasma generator. Optionally, the reagent may be mixed with the effluent prior to introduction into the plasma generator.

During operation 368, a plasma is generated from the reagent and the effluent within the plasma generator. Generation of the plasma ionizes one or both of the effluent and the reagent. Ionization of the effluent and reagent promotes reactions between the ionized species. As the ionized reagent and/or ionized effluent exit the plasma generator, the ionized species react with one another to form gas phase effluent materials. The gas phase effluent materials are non-pyrophoric materials that remain in the gas phase at conditions found within an abatement system during processing. The gas phase effluent material may then exit the abatement system for further treatment, such as scrubbing.

In a representative abatement process, an effluent containing one or more of P, B, As, PH₃, BF₃, AsH₃, and derivatives thereof is exhausted from a processing chamber. The effluent flows through a TMP into a foreline. A reagent, such as NF₃ in a carrier gas of argon, is supplied from a reagent delivery system to the foreline. The reagent and the effluent flow through the foreline to a plasma generator, where the plasma generator dissociates the effluent and the reagent into ionized species. The NF₃ may be provided at a flow rate of about 10 sccm to about 20 sccm for a 200 mm substrate to generate fluorine ions which react with the pyrophoric byproducts in the effluent. Argon may be provided at a flow rate sufficient to facilitate plasma generation. As the ionized species exit the plasma generator, the ionized species combine into gas phase effluent material, e.g., effluent products which remain in the gas phase at temperature/pressure conditions within the abatement system. In one example, the gas phase effluent materials include one or more of PF₃, PF₅, BF₃, AsF₃, F₂, HF, and N₂. The gas phase effluent materials may be further exhausted through a vacuum source, such as a roughing pump, and then to a scrubber, without condensing within the abatement system.

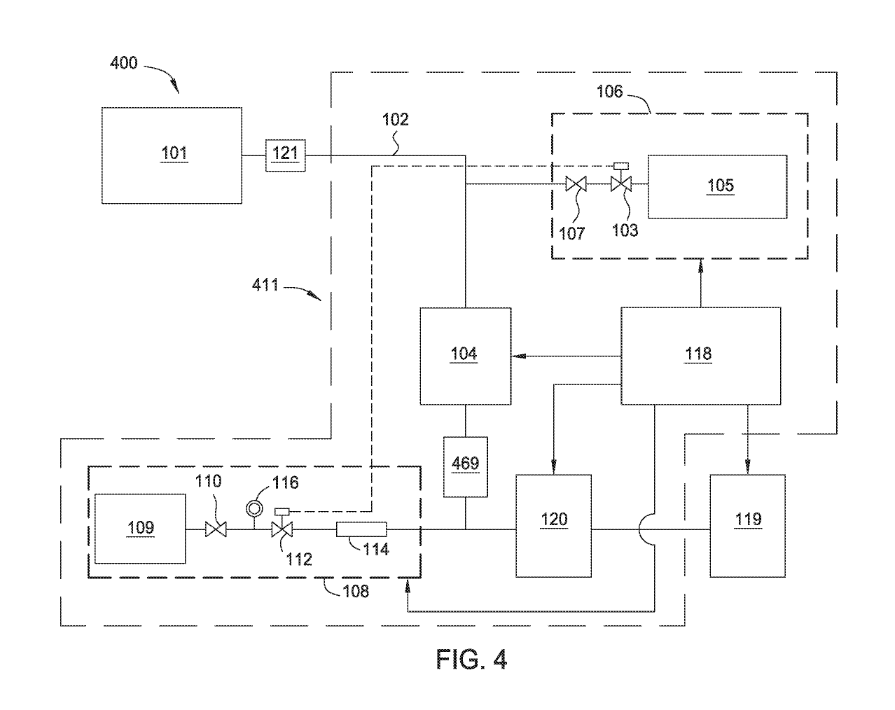

FIG. 4 depicts a schematic diagram of a processing system 400 in accordance with another embodiment of the disclosure. The processing system 400 is similar to the processing system 100. However, the processing system 400 includes an abatement system 411 that includes a trap 469. The trap 469 is positioned in line between the plasma generator 104 and the vacuum source 120. The trap 469 may be a mesh filter, a condenser, or the like, that is adapted to remove particulate matter from an effluent stream. Thus, in contrast to the processing system 100 which reacts pyrophoric byproducts into compounds which remain in a gas phase throughout abatement, the processing system 400 reacts the pyrophoric byproducts to generate effluent material which precipitates or condenses out of the gas phase and is trapped in the trap 469. Because the products are trapped in the trap 469, the products do not condense in undesired locations of the processing system 400. In one example, the reagent source 105 may be a water vapor generator.

FIG. 5 is a flow diagram illustrating one embodiment of a method 575 of abating effluent exiting a processing chamber. The method 575 begins at operation 576. In operation 576, an effluent containing a pyrophoric byproduct is exhausted from a processing chamber, such as the processing chamber 101, into a plasma generator, such as the plasma generator 104. A pump 121, such as a TMP, facilitates removal of the effluent from the processing chamber. During operation 577, a reagent is introduced to the plasma generator. Optionally, the reagent may be mixed with the effluent prior to introduction in to the plasma generator. In one example, the reagent is an oxidizing agent.

During operation 578, a plasma is generated from one or more of the reagent and the effluent within the plasma generator. Generation of the plasma facilitates ionization of one or both of the effluent and the reagent. Ionization of the effluent and reagent promotes reactions between the ionized species, e.g., between the reagent and the pyrophoric byproducts within the effluent. As the ionized reagent and/or ionized effluent exit the plasma generator, the ionized species react with one another to form condensed particulate matter. The condensed particulate matter is non-pyrophoric material that is in the solid phase at conditions found within an abatement system. In operation 579, the condensed particulate matter is trapped, for example, in a trap 469. Entrapment of the condensed particulate matter facilitates collection and removal of the condensed particulate matter of from the abatement system. Because of the reaction between the pyrophoric byproduct with the reagent in operation 578, the resultant condensed particulate matter is not pyrophoric, and therefore, cleaning of the trap is safer than cleaning trapped pyrophoric byproducts. After trapping the condensed particulate matter in operation 579, the remaining effluent gas may then exit the abatement system for further treatment, such as scrubbing.

In a representative abatement process, an effluent containing one or more of P, B, As, PH₃, BF₃, AsH₃, and derivatives thereof is exhausted from a processing chamber. The effluent flows through a TMP into a foreline. A reagent, such as O₂ in a carrier gas of argon is supplied from a reagent delivery system to the foreline. The reagent and the effluent flow through the foreline to a plasma generator, where the plasma generator dissociates the effluent and the reagent into ionized species. The O₂ may be provided at a flow rate of about 10 sccm to about 30 sccm for a 200 mm substrate to generate oxygen ions which react with the pyrophoric byproducts in the effluent. Argon may be provided at a flow rate sufficient to facilitate plasma generation. As the ionized species exit the plasma generator, the ionized species react, e.g., combust, to form condensed particulate matter. In one example, the condensed particulate matter includes one or more of P₂O₃, P₂O₅, B₂O₃, and As₂O₅, among others. The condensed particulate matter is then trapped to remove the condensed particulate matter from the effluent gas. The effluent gas may then be exhausted through a vacuum source, such as a roughing pump, and then to a scrubber.

The previously described embodiments have many advantages. For example, the techniques disclosed herein can convert pyrophoric byproducts in effluent gas into more benign chemicals that can be more safely handled. The plasma abatement process is beneficial to human health in terms of acute exposure to the effluent by workers and by conversion of pyrophoric or toxic materials into more environmentally friendly and stable materials. The plasma abatement process also protects semiconductor processing equipment, such as, for example, vacuum pumps, from excessive wear and premature failure by removing particulates and/or other corrosive materials from the effluent stream. Moreover, performing the abatement technique on the vacuum foreline adds additional safety to workers and equipment. If an equipment leak occurs during the abatement process, the low pressure of the effluent relative to the outside environment prevents the effluent from escaping the abatement equipment. Additionally, many of the abating reagents disclosed herein are low-cost and versatile. It is not necessary for all embodiments to have all the advantages.

While the foregoing is directed to embodiments of the disclosed devices, methods and systems, other and further embodiments of the disclosed devices, methods and systems may be devised without departing from the basic scope thereof, and the scope thereof is determined by the claims that follow.

What is claimed is:

1. A method, comprising:
flowing an effluent from a processing chamber into a plasma generator, wherein the effluent comprises a pyrophoric material;
flowing a reagent into the plasma generator;
ionizing one or more of the pyrophoric material and the reagent;
after the ionizing, reacting the pyrophoric material with the reagent to generate a gas phase effluent material; and
abating the gas phase effluent material.

2. The method of claim 1, wherein the processing chamber comprises an ion implant chamber.

3. The method of claim 1, wherein the pyrophoric material comprises one or more of P, B, As, PH₃, BF₃, and AsH₃.

4. The method of claim 1, wherein the reagent comprises NF₃.

5. The method of claim 4, wherein the reagent has a flow rate within a range of about 10 sccm to about 20 sccm for a 200 mm substrate.

6. The method of claim 1, wherein the reacting occurs prior to introducing the pyrophoric material to a roughing pump.

7. The method of claim 6, further comprising introducing the gas phase effluent material to a scrubber.

8. A method of abating effluent from a processing chamber, comprising:
flowing an effluent from a processing chamber into a plasma generator, wherein the effluent comprises a pyrophoric material;
flowing a reagent into the plasma generator;
ionizing one or more of the pyrophoric material and the reagent;
after the ionizing, reacting the pyrophoric material with the reagent to generate condensed particulate matter; and
trapping the condensed particulate matter.

9. The method of claim 8, wherein the reagent is an oxidizing source.

10. The method of claim 8, wherein the reagent comprises one or more of oxygen and water vapor.

11. The method of claim 8, wherein the reagent is oxygen, and wherein the reagent has a flow rate within a range of about 10 sccm to about 30 sccm for a 200 mm substrate.

12. The method of claim 8, wherein the pyrophoric material comprises one or more of P, B, As, PH₃, BF₃, AsH₃.

13. The method of claim 8, wherein the processing chamber is an ion implant chamber.

14. The method of claim 8, wherein the trapping occurs prior to introducing the pyrophoric material to a roughing pump.

15. An apparatus for abating effluent from a processing chamber, comprising:
an ion implant chamber;
a foreline coupled to the ion implant chamber for exhausting effluent from the ion implant chamber;
a plasma generator for generating ionized gases within the foreline;
a vacuum source coupled to the foreline downstream of the plasma generator; and
a scrubber fluidly coupled to the vacuum source.

16. The apparatus of claim 15, further comprising a reagent source coupled to the foreline, the reagent source comprising an oxidizing agent.

17. The apparatus of claim 15, further comprising a reagent source coupled to the foreline, the reagent source comprising NF₃.

18. The apparatus of claim 15, further comprising a trap positioned downstream of the plasma generator and upstream of the vacuum source.

19. The apparatus of claim 15, wherein the plasma generator is an inductively coupled plasma generator.

20. The apparatus of claim 15, further comprising a reagent source coupled to the foreline upstream of the plasma generator, wherein the reagent source is a water vapor generator.
